(19) United States
(12) Patent Application Publication
(10) Pub. No.: US 2026/0134807 A1
(43) Pub. Date: May 14, 2026

(54) DRIVING CIRCUIT FOR POWER CONSUMPTION REDUCTION AND OPERATION METHOD FOR REDUCING POWER CONSUMPTION OF A DRIVING CIRCUIT

(71) Applicant: NOVATEK MICROELECTRONICS CORP., HSINCHU (TW)

(72) Inventor: YEN-CHENG CHENG, HSINCHU CITY (TW)

(21) Appl. No.: 18/943,018

(22) Filed: Nov. 11, 2024

(51) Int. Cl. G09G 3/20; H03F 1/02; H03F 3/45

(52) U.S. Cl. CPC G09G 3/20; H03F 1/0205; H03F 3/45475; G09G 2310/0289; G09G 2310/0291; G09G 2330/021

(57) ABSTRACT

A driving circuit and operation method for reducing power consumption of the driving circuit are provided. The proposed driving circuit is operable to drive a display panel and comprises at least one operational amplifier. An input voltage of the operational amplifier is examined and determined such that a first operation voltage and a second operation voltage of the operational amplifier can be provided. Since the first and second operation voltages of the operational amplifier are adjustable and can be decided associated with its input voltage, the operational amplifier is able to operate in an adaptive voltage range between the first and second operation voltages. As a result, power consumption reduction of the driving circuit can be achieved. As such, it is believed that the present invention is significantly effective in realizing power efficiency optimization result of a driving circuit when it is applied to drive a display panel device.

### BACKGROUND OF THE INVENTION

### Field of the Invention

The present invention is related to a power consumption reduction technology. More particularly, the present invention is directed to a driving circuit which is applicable to drive a display panel and its operation method thereof, in which by designing an operational amplifier in the driving circuit to work in an adaptive voltage range, power consumption reduction of the driving circuit can be accomplished.

### Description of the Related Arts

As known, display driver ICs are integrated circuit chips which are mostly applied to control the operations and display functions of a display panel device, such as a liquid crystal display (LCD) panel device or an active-matrix organic light-emitting diode (AMOLED) panel device. Overall, the main function of the display driver ICs includes to convert driving signals and data into electrical signals and transmit the converted electrical signals to the display panel so as to control the panel device. In addition, since a display driver integrated circuit (DDI) is a key component for driving a display panel device and transmitting signals including images and data to the display panel device in the form of electrical signals to display texts and/or images on the screen, the demands for display driver ICs are significantly continuing to increase in recent years. The applications of the display driver integrated circuits include not only to liquid crystal display (LCD) panel devices and plasma display panel (PDP) devices, but also to organic light-emitting diode (OLED) panel devices and several other various panel devices.

However, what draws our attention is that, when regarding a display driver IC, an operational amplifier is usually adopted for generating output signals, and the operation voltage of the operational amplifier disposed in the display driver IC, is usually fixed within a certain voltage range. Since the power consumption P of the display driver IC is determined by the current I flowing through the operational amplifier, as well as the operation voltage V of the operational amplifier, where (P=V*I), it is inevitable that the power consumption P of the display driver IC will enormously increase as more operational amplifiers are used, since (P=V*I*N), where N stands for the number of operational amplifiers disposed in the display driver IC. Please refer to FIG. 1, which shows a schematic diagram of a conventional display driver IC architecture applied to generate output signals in the same polarity in the related art. In FIG. 1, the power consumption P1 of the display driver IC is equal to (P1=VDDA*I_OP1), where I_OP1 is the current flowing through the operational amplifier OP1 and VDDA is the operation voltage of the operational amplifier OP1.

In addition, FIG. 2 and FIG. 3 furthermore disclose each of a schematic diagram of a conventional display driver IC architecture applied to generate output signals having the opposite polarities in the related art. As shown in FIG. 2, the power consumption P2 of the display driver IC is equal to (P2=(VDDA*I_OP2)/2), where I_OP2 is the current flowing through the operational amplifier OP2, and one operational amplifier OP2 is electrically coupled between an operation voltage VDDA and half of the operation voltage HVDDA, while the other operational amplifier OP2 is electrically coupled between half of the operation voltage HVDDA and a ground voltage GNDA. FIG. 3 shows another practicable configuration in the prior art for generating output signals having the opposite polarities in the prior art. As indicated in FIG. 3, one of the operational amplifier OP3 can be alternatively in electrical connection between a positive analog operation voltage PAVDD and a ground voltage GNDA, while the other operational amplifier OP3 can be alternatively in electrical connection between the ground voltage GNDA and a negative analog operation voltage NAVDD. According to such various configuration shown in FIG. 3, then the power consumption P3 of the display driver IC is equal to the following equation:
P3=((PAVDD*I_OP3)/2)+((|NAVDD|*I_OP3)/2), where I_OP3 is the current flowing through the operational amplifier OP3, PAVDD is the positive analog operation voltage of the operational amplifier OP3, for example, PAVDD can be +6V; and NAVDD is the negative analog operation voltage of the operational amplifier OP3, for example, NAVDD can be −6V. As people skilled in the technical fields have known, an average power consumption of the display panel system is directed to the average power consumption of its display driver IC. Therefore, it makes power consumption of the display driver IC a very noticeable performance parameter. Since it is acknowledged that an overall power consumption of the display panel may be enormously increased and the power consumption of a display driving IC circuit is still an issue to be overcome, it is evident that continual improvements in power efficiency reduction remain desirable. In order to ensure that display panels, such as OLED displays, or micro-LED displays do not consume too much power, several methods have been discussed these days in the current technology and yet, challenges are still remained. Further reductions in power consumption and alternative methodologies in the field are still to be expected.

As a result, it, in view of all, should be apparent and obvious that there is indeed an urgent need for the professionals in the field for a novel and inventive display driving circuit as well as its operation method thereof, to be developed, so as to solve the above-mentioned issues, and to enhance the power reduction efficiency in a display panel device.

### SUMMARY OF THE INVENTION

In order to overcome the above-mentioned disadvantages, one major objective in accordance with the present invention is to provide a novel driving circuit structure and an operation method of the driving circuit for reducing power consumption when it is applied to drive a display panel.

By employing the proposed driving circuit and its operation method thereof, an optimal power reduction efficiency of the display panel in which the driving circuit is applicable to drive, can be achieved. The present invention is aimed to modify and improve the deficiencies regarding power waste occurring in the related arts and to suppress redundant power waste in a display panel device.

According to the technical contents of the present invention, the disclosed driving circuit and the disclosed operation method of the driving circuit are illustrated as being applicable to drive a display panel device, for example. However, the present invention is certainly not limited thereto. The proposed driving circuit and the disclosed operation method thereof as provided in the present invention may also be applied to other circuit configurations of various display panel devices. Many alternatives and modifications will be apparent to those skilled in the art, once informed by the present disclosure.

According to one major embodiment of the present invention, a driving circuit which is applicable to drive a display panel for power consumption reduction is to be provided hereinafter. The proposed driving circuit includes a level shifter circuit, a digital to analog converter and an operational amplifier. The digital to analog converter is configured as being electrically connected with the level shifter circuit. And the operational amplifier is disposed as being electrically connected with the digital to analog converter, such that an output voltage of the digital to analog converter is an input voltage of the operational amplifier.

According to the embodiment of the present invention, the operational amplifier is electrically supplied with a first operation voltage and a second operation voltage, and the first operation voltage and the second operation voltage are decided associated with the input voltage of the operational amplifier. By adopting such design manners, the operational amplifier is able to work in an adaptive voltage range between the first operation voltage and the second operation voltage for power consumption reduction of the driving circuit, since the first operation voltage and the second operation voltage of the operational amplifier are adjustable.

According to the embodiment of the present invention, since the input voltage of the operational amplifier is generated from the output voltage of the digital to analog converter, the first operation voltage and the second operation voltage of the operational amplifier are given as analog voltage values.

According to a first embodiment of the present invention, the adaptive voltage range between the first operation voltage and the second operation voltage of the operational amplifier can be in a range between a power supply voltage VDDA and half of the power supply voltage HVDDA (VDDA□HVDDA), between half of the power supply voltage HVDDA and a ground voltage GNDA (HVDDA□GNDA), or between the power supply voltage VDDA and the ground voltage GNDA (VDDA□GNDA).

According to a second embodiment of the present invention, the adaptive voltage range between the first operation voltage and the second operation voltage of the operational amplifier may alternatively be in a range between a power supply voltage VDDA and two-thirds of the power supply voltage 2*VDDA/3 (VDDA□2*VDDA/3), between two-thirds of the power supply voltage 2*VDDA/3 and one-third of the power supply voltage 1*VDDA/3 (2*VDDA/3□1*VDDA/3), or between one-third of the power supply voltage 1*VDDA/3 and a ground voltage GNDA (1*VDDA/3□GNDA).

Alternatively, according to a third embodiment of the present invention, then the adaptive voltage range between the first operation voltage and the second operation voltage of the operational amplifier may alternatively be in a range between a power supply voltage VDDA and three quarters of the power supply voltage 3*VDDA/4 (VDDA□3*VDDA/4), between three quarters of the power supply voltage 3*VDDA/4 and half of the power supply voltage 2*VDDA/4 (3*VDDA/4□2*VDDA/4), between half of the power supply voltage 2*VDDA/4 and one quarter of the power supply voltage 1*VDDA/4 (2*VDDA/4□1*VDDA/4), or between one quarter of the power supply voltage 1*VDDA/4 and the ground voltage GNDA (1*VDDA/4□GNDA).

In order to control the operational amplifier of the driving circuit to alternatively connect with the adjustable voltage range, it is feasible to dispose a plurality of switching components (switches), which are electrically coupled with the operational amplifier. As a result, by controlling an on and off state of either of the switching components, the disclosed operational amplifier of the driving circuit is able to operate in an adjustable voltage domain according to its input voltage value. And power consumption reduction can be achieved.

In another aspect, the present invention is also aimed to provide an operation method for reducing power consumption of a driving circuit, and the disclosed operation method for reducing power consumption of the driving circuit includes a plurality of the following steps:
(a) determining an input voltage of the operational amplifier of the driving circuit;
(b) providing a first operation voltage and a second operation voltage according to the input voltage of the operational amplifier; and
(c) electrically connecting the operational amplifier with the first operation voltage and the second operation voltage, wherein the first operation voltage and the second operation voltage are decided associated with the input voltage of the operational amplifier, such that the operational amplifier is able to work in an adaptive voltage range between the first operation voltage and the second operation voltage for power consumption reduction of the driving circuit.

In addition, when the Application is brought into practical application field, for instance, when there are a plurality of the operational amplifiers being further disposed in the driving circuit, then the adaptive voltage range between the first operation voltage and the second operation voltage in each of the plurality of the operational amplifiers can be identical (in the same voltage range) such that the plurality of the operational amplifiers are able to share common circuit layout (for example, a well region) for circuit layout area reduction. In view of the current technologies, it is verified that a plurality of display patterns, including a pixel checker display pattern, a sub-pixel checker display pattern and an R/G/B display pattern of a display panel, can be successfully obtained with the merits of less power consumption.

Therefore, by employing the present invention, it is believed that redundant power waste can be avoided, and optimization of power efficiency in a display panel device can be greatly achieved.

It is believed that the applicants of the invention have proposed the disclosed operation method for reducing power consumption of the driving circuit and the driving circuit structure, as above mentioned. By adopting the proposed technical contents of the invention, it is to be understood that, the above driving circuit scheme architecture and its operation method thereof may be applied to any various display panel devices, and is not limited by any of the disclosed embodiments of the present invention. Thereby, it is believed that the present invention achieves to successfully solve the problems of related arts and performs as being highly competitive and able to be widely utilized in any related industries.

To sum up, it has been proved and verified that the present invention is sophisticatedly designed, and the whole new driving techniques and driving circuit structures can be effectively employed in the existing display panel devices while compared to the related arts. These and other objectives of the present invention will become obvious to those of ordinary skill in the art after reading the following detailed description of preferred embodiments. And it is to be understood that both the foregoing general description and the following detailed description are exemplary and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings:

FIG. 1 shows a schematic diagram of a conventional display driver IC architecture applied to generate output signals in the same polarity in the related art.

FIG. 2 shows a schematic diagram of a conventional display driver IC architecture applied to generate output signals having the opposite polarities in the related art.

FIG. 3 shows another schematic diagram of a conventional display driver IC architecture applied to generate output signals having the opposite polarities in the related art.

FIG. 4 shows a diagram schematically illustrating a driving circuit which is applicable to drive a display panel in accordance with a first embodiment of the present invention.

FIG. 5 shows a flow chart illustrating a plurality of steps of the disclosed operation method for reducing power consumption of the driving circuit in accordance with one embodiment of the present invention.

FIG. 6 schematically shows a state diagram of the disclosed driving circuit operating in an adaptive voltage range between a power supply voltage VDDA and half of the power supply voltage HVDDA based on the FIG. 4 embodiment.

FIG. 7 schematically shows another state diagram of the disclosed driving circuit operating in another adaptive voltage range between half of the power supply voltage HVDDA and a ground voltage GNDA based on the FIG. 4 embodiment.

FIG. 8 schematically shows one another state diagram of the disclosed driving circuit operating in one another adaptive voltage range between the power supply voltage VDDA and the ground voltage GNDA based on the FIG. 4 embodiment.

FIG. 9 schematically shows a display frame of a display panel in accordance with adopting the embodiment of the present invention when the driving circuit for power consumption reduction is used to drive the display panel.

FIG. 10 schematically shows a state diagram of the disclosed driving circuit operating in an adaptive voltage range between a power supply voltage VDDA and two-thirds of the power supply voltage 2*VDDA/3 in accordance with a second embodiment of the present invention.

FIG. 11 schematically shows a state diagram of the disclosed driving circuit operating in an adaptive voltage range between two-thirds of the power supply voltage 2*VDDA/3 and one-third of the power supply voltage 1*VDDA/3 in accordance with a second embodiment of the present invention.

FIG. 12 schematically shows a state diagram of the disclosed driving circuit operating in an adaptive voltage range between one-third of the power supply voltage 1*VDDA/3 and a ground voltage GNDA in accordance with a second embodiment of the present invention.

FIG. 13 schematically shows a state diagram of the disclosed driving circuit operating in an adaptive voltage range between a power supply voltage VDDA and three quarters of the power supply voltage 3*VDDA/4 in accordance with a third embodiment of the present invention.

FIG. 14 schematically shows a state diagram of the disclosed driving circuit operating in an adaptive voltage range between three quarters of the power supply voltage 3*VDDA/4 and half of the power supply voltage 2*VDDA/4 in accordance with a third embodiment of the present invention.

FIG. 15 schematically shows a state diagram of the disclosed driving circuit operating in an adaptive voltage range between half of the power supply voltage 2*VDDA/4 and one quarter of the power supply voltage 1*VDDA/4 in accordance with a third embodiment of the present invention.

FIG. 16 schematically shows a state diagram of the disclosed driving circuit operating in an adaptive voltage range between one quarter of the power supply voltage 1*VDDA/4 and a ground voltage GNDA in accordance with a third embodiment of the present invention.

FIG. 17 schematically shows a flow chart illustrating a process method for determining the adaptive voltage range between the first operation voltage and the second operation voltage of the operational amplifier in the driving circuit when there are a plurality of operational amplifiers disposed in the driving circuit according to the present invention.

FIG. 18 shows the determination criteria according to the flow chart in FIG. 17 of the present invention.

FIG. 19 shows a pixel checker display pattern of a display panel device when adopting the disclosed driving circuit for power consumption reduction in accordance with the embodiment of the present invention.

FIG. 20 shows a sub-pixel checker display pattern of a display panel device when adopting the disclosed driving circuit for power consumption reduction in accordance with the embodiment of the present invention.

FIG. 21 shows an R/G/B display pattern of a display panel device when adopting the disclosed driving circuit for power consumption reduction in accordance with the embodiment of the present invention.

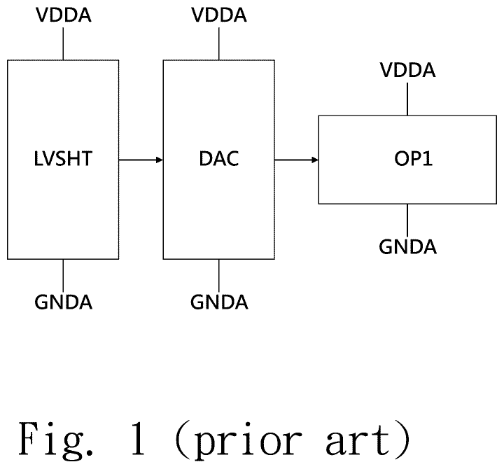

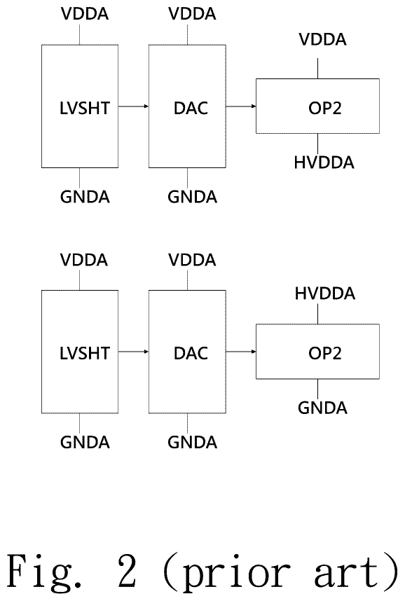

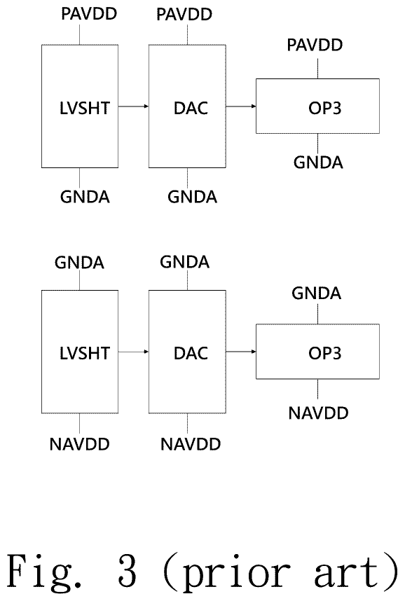

### DESCRIPTION OF THE PREFERRED EMBODIMENTS

Reference will now be made in detail to embodiments illustrated in the accompanying drawings. Wherever possible, the same reference numbers will be used in the drawings and the description to refer to the same or like parts. In the drawings, the shape and thickness may be exaggerated for clarity and convenience. This description will be directed in particular to elements forming part of, or cooperating more directly with, methods and apparatus in accordance with the present disclosure. It is to be understood that elements not specifically shown or described may take various forms well known to those skilled in the art. Many alternatives and modifications will be apparent to those skilled in the art, once informed by the present disclosure.

Unless otherwise specified, some conditional sentences or words, such as “can”, “could”, “might”, or “may”, usually attempt to express that the embodiment in the invention has, but it can also be interpreted as a feature, element, or step that may not be needed. In other embodiments, these features, elements, or steps may not be required.

Reference throughout this specification to “one embodiment” or “an embodiment” means that a particular feature, structure, or characteristic described in connection with the embodiment is included in at least one embodiment. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

Certain terms are used throughout the description and the claims to refer to particular components. One skilled in the art appreciates that a component may be referred to as different names. This disclosure does not intend to distinguish between components that differ in name but not in function. In the description and in the claims, the term “comprise” is used in an open-ended fashion, and thus should be interpreted to mean “include, but not limited to.” The phrases “be coupled to,” “couples to,” and “coupling to” are intended to compass any indirect or direct connection. Accordingly, if this disclosure mentioned that a first device is coupled with a second device, it means that the first device may be directly or indirectly connected to the second device through electrical connections, wireless communications, optical communications, or other signal connections with/without other intermediate devices or connection means.

The invention is particularly described with the following examples which are only for instance. Those skilled in the art will readily observe that numerous modifications and alterations of the device and method may be made while retaining the teachings of the invention. Accordingly, the following disclosure should be construed as limited only by the metes and bounds of the appended claims. In the whole patent application and the claims, except for clearly described content, the meaning of the article “a” and “the” includes the meaning of “one or at least one” of the element or component. Moreover, in the whole patent application and the claims, except that the plurality can be excluded obviously according to the context, the singular articles also contain the description for the plurality of elements or components. In the entire specification and claims, unless the contents clearly specify the meaning of some terms, the meaning of the article “wherein” includes the meaning of the articles “wherein” and “whereon”. The meanings of every term used in the present claims and specification refer to a usual meaning known to one skilled in the art unless the meaning is additionally annotated. Some terms used to describe the invention will be discussed to guide practitioners about the invention. Every example in the present specification cannot limit the claimed scope of the invention.

In the following descriptions, a driving circuit for power consumption reduction and an operation method for reducing power consumption of the driving circuit will be provided. The disclosed driving circuit and the disclosed operation method for reducing power consumption of the driving circuit are proposed to enhance the power reduction efficiency in a display driving circuit architecture, which is applicable to drive a display panel, such that optimization of the power consumption of the display panel can be achieved. Hereinafter, the proposed driving circuit and the proposed operation method for reducing power consumption of the driving circuit are disclosed as being applied to a display driver integrated chip (IC). However, the present invention is certainly not limited thereto. Alternatively, the disclosed technologies regarding the proposed driving circuit and the proposed operation method thereof, as provided below may also be applied to other circuit configurations. And the claim scope of the present invention covers all the equality.

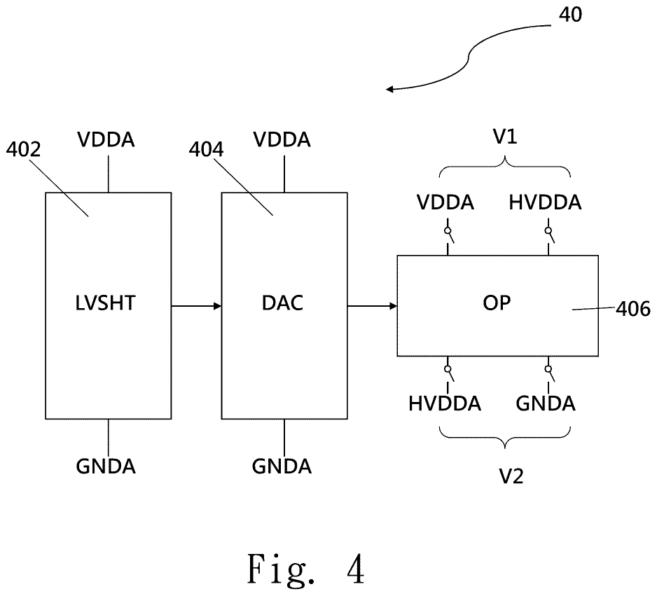

In the beginning, please refer to FIG. 4 first, which shows a diagram schematically illustrating a driving circuit which is applicable to drive a display panel in accordance with a first embodiment of the present invention. As illustrated in the first embodiment in FIG. 4, the proposed driving circuit 40 includes a level shifter circuit (LVSHT) 402, a digital to analog converter (DAC) 404 and an operational amplifier (OP) 406. According to the embodiment, the digital to analog converter 404 is being electrically connected with the level shifter circuit 402, and the operational amplifier 406 is further electrically connected with the digital to analog converter 404 so as to generate output signals for driving a display panel. As can be seen, an output voltage of the digital to analog converter 404 is an input voltage of the operational amplifier 406, and the operational amplifier 406 is electrically supplied with a first operation voltage V1 and a second operation voltage V2. According to the technical solution of the present invention, by adjusting the first operation voltage V1 and the second operation voltage V2 to which the operational amplifier 406 is electrically connected, the power consumption of the operational amplifier 406 can be optimized for power reduction. And moreover, as the power consumption of the operational amplifier 406 can be reduced, the overall power consumption of the display panel which the driving circuit 40 is used to drive, can be reduced at the same time.

In details, according to the technical solution of the present invention, the first operation voltage V1 and the second operation voltage V2 are decided associated with the input voltage of the operational amplifier 406. In other words, the first operation voltage V1 and the second operation voltage V2 are determined and given to the operational amplifier 406 according to its input voltage, generated from its previous digital to analog converter 404 connected at a previous stage. By adopting such technical characteristics, it can be derived that the operational amplifier 406 is able to work in an adaptive voltage range between the first operation voltage V1 and the second operation voltage V2 for power consumption reduction of the driving circuit 40.

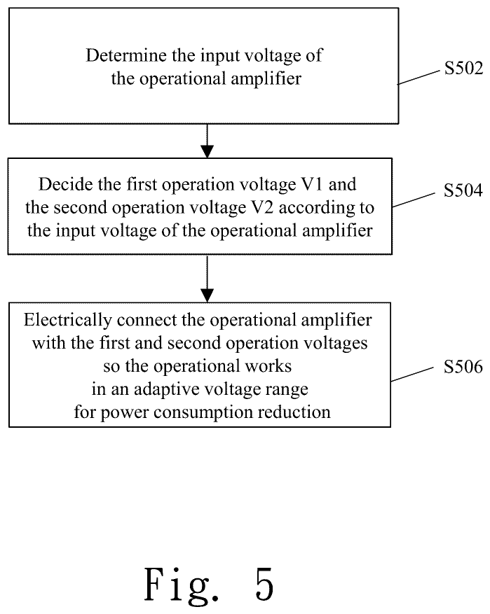

Please refer to FIG. 5, which shows a flow chart illustrating the steps of the disclosed operation method for reducing power consumption of the driving circuit in accordance with one embodiment of the present invention. The disclosed operation method of the driving circuit includes the steps of S502, S504 and S506. For better understandings, please find the flow chart in FIG. 5 accompanying the structure in FIG. 4. At first, the input voltage of the operational amplifier 406 is detected and determined in the step of S502. After, as indicated in the step of S504, according to the input voltage, the first operation voltage V1 and the second operation voltage V2 will be decided and provided to the operational amplifier 406. As a result, when performing the step of S506, the operational amplifier 406 is electrically connected with the first operation voltage V1 and with the second operation voltage V2, wherein the first operation voltage V1 and the second operation voltage V2 are decided associated with the input voltage of the operational amplifier, such that the operational amplifier 406 is able to work in an adaptive voltage range between the first operation voltage V1 and the second operation voltage V2 for power consumption reduction of the driving circuit.

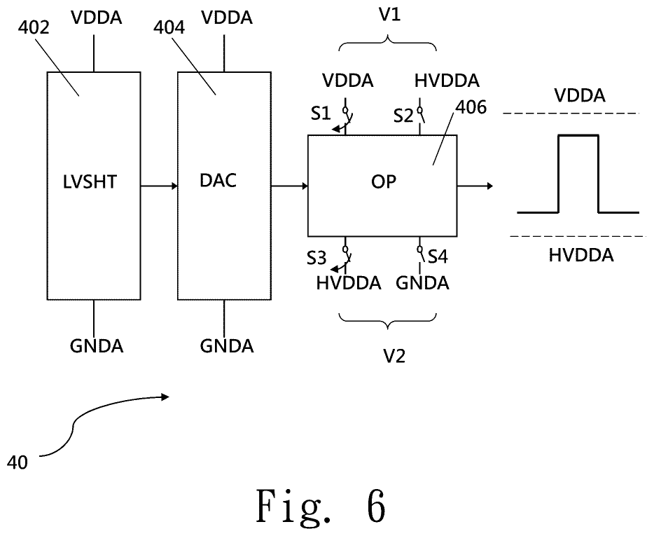

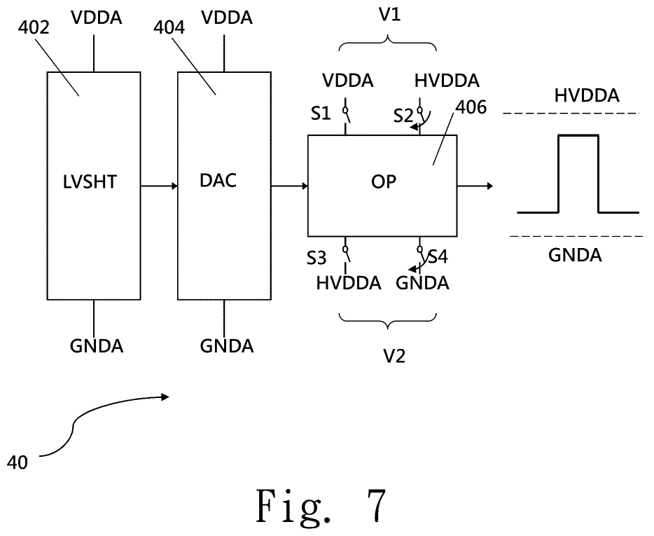

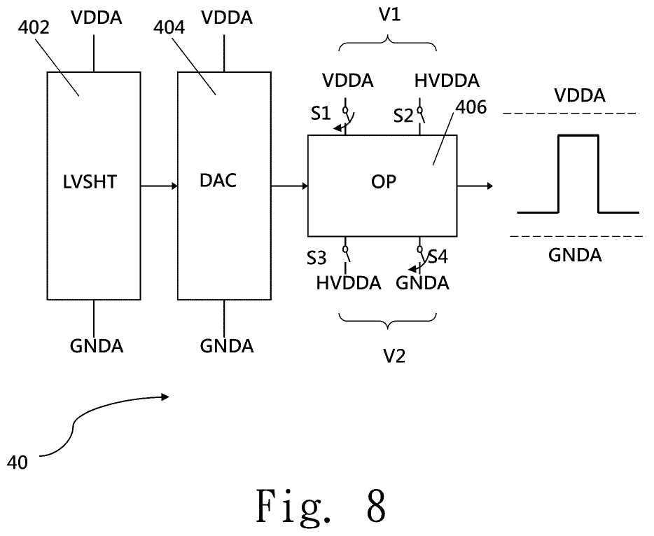

Please refer to FIG. 6, FIG. 7 and FIG. 8, which individually shows a state diagram of the disclosed driving circuit 40 operating in a various adaptive voltage range based on the FIG. 4 embodiment. As can be seen, the operational amplifier 406 is electrically connected with a first switch S1, a second switch S2, a third switch S3 and a fourth switch S4. By disposing the plurality of switches S1˜S4, the operational amplifier 406 can be alternatively connected with a power supply voltage (VDDA) or with half of the power supply voltage (HVDDA) as the first operation voltage V1 through the first switch S1 or the second switch S2. In addition, the operational amplifier 406 can be also alternatively connected with half of the power supply voltage (HVDDA) or with the ground voltage (GNDA) as the second operation voltage V2 through the third switch S3 or the fourth switch S4. Since the operational amplifier 406 is connected with the digital to analog converter 404, and the input voltage of the operational amplifier 406 is an output voltage of the digital to analog converter 404, it is believed that the first operation voltage V1 and the second operation voltage V2 of the operational amplifier 406 are given as analog voltage values. As such, according to the embodiment of the present invention, the power supply voltage is illustrated as a power supply analog voltage “VDDA” in the figures, half of the power supply voltage is illustrated as a half power supply analog voltage “HVDDA” in the figures, and the ground voltage is illustrated as a ground analog voltage “GNDA” in the figures.
1. According to one state diagram of the disclosed driving circuit 40 as shown in FIG. 6, when the input voltage of the operational amplifier 406 is in a range between a power supply voltage (VDDA) and half of the power supply voltage (HVDDA), then the first switch S1 and the third switch S3 are closed (while the second switch S2 and the fourth switch S4 are open), such that the first operation voltage V1 is determined and given as the power supply voltage (VDDA) and the second operation voltage V2 is determined and given as half of the power supply voltage (HVDDA), respectively.
2. According to another state diagram of the disclosed driving circuit 40 as shown in FIG. 7, when the input voltage of the operational amplifier 406 is in a range between half of the power supply voltage (HVDDA) and a ground voltage (GNDA), then the second switch S2 and the fourth switch S4 are closed (while the first switch S1 and the third switch S3 are open), such that the first operation voltage V1 is determined and given as half of the power supply voltage (HVDDA) and the second operation voltage V2 is determined and given as the ground voltage (GNDA), respectively.
3. According to one another state diagram of the disclosed driving circuit 40 as shown in FIG. 8, when the input voltage of the operational amplifier 406 is in a range between a third operation voltage and a fourth operation voltage, and the third operation voltage is slightly greater than half of the power supply voltage (HVDDA), and the fourth operation voltage is slightly less than half of the power supply voltage (HVDDA), under such circumstances, then the first switch S1 and the fourth switch S4 are closed (while the second switch S2 and the third switch S3 are open), such that such that the first operation voltage V1 is determined and given as the power supply voltage (VDDA) and the second operation voltage V2 is determined and given as the ground voltage (GNDA), respectively.

On account of the above technical contents of the present invention, it can be derived that by employing the adjustable first and second operation voltages V1 and V2 to the operational amplifier of a driving circuit, the present invention achieves in controlling the operational amplifier to work in an adaptive voltage range between the adjustable first operation voltage V1 and the adjustable second operation voltage V2, such that a driving circuit power consumption reduction objective of the present invention can be effectively accomplished.

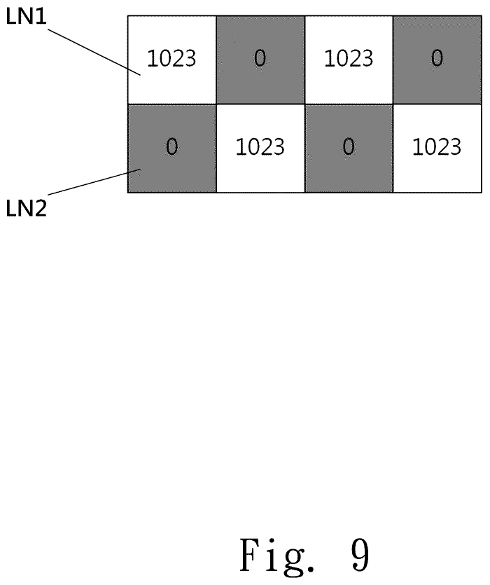

Please refer to FIG. 9, which schematically shows a display frame of a display panel in accordance with adopting the embodiment of the present invention when the driving circuit for power consumption reduction is used to drive the display panel. As can be seen, each row of the display frame indicates one line LN1 and LN2 comprising a plurality of channels. When the disclosed driving circuit is applied to drive the display panel, it can be feasible that one operational amplifier of the driving circuit can be operating and supplied in a range between the power supply voltage VDDA and half of the power supply voltage HVDDA (VDDA□HVDDA), while another operational amplifier of the driving circuit can be operating and supplied in a range between half of the power supply voltage HVDDA and the ground voltage GNDA (HVDDA□GNDA), then during the charging and discharging of the display panel, charge reuse can be generated and thus power saving efficiency is achieved. In view of FIG. 9, it is evident that the present invention is effective and power reduction of the display panel is successfully accomplished.

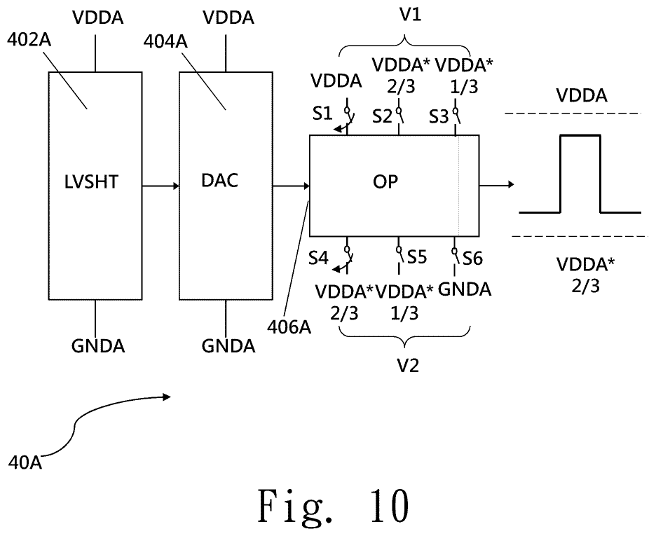

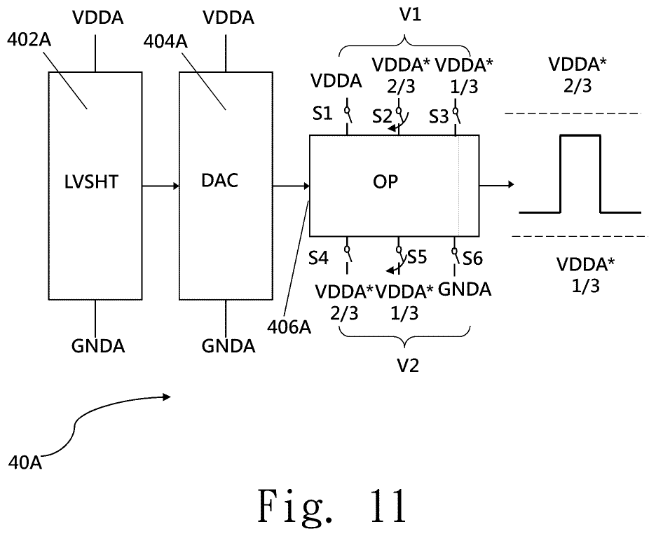

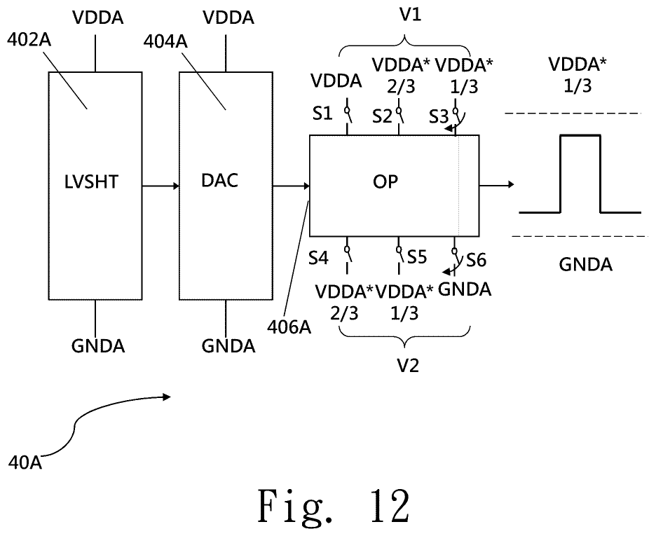

Nevertheless, it is worth emphasizing that the disclosed operational amplifier of the driving circuit according to the present invention is certainly not limited by working in an adaptive voltage range between (VDDA□HVDDA), (HVDDA□GNDA), or (VDDA□GNDA) as disclosed in the previous embodiment in FIG. 6□FIG. 8. Please refer to FIG. 10, FIG. 11 and FIG. 12, wherein each of the figures respectively shows another various state diagram of the disclosed driving circuit 40A operating in another various adaptive voltage range in accordance with a second embodiment of the present invention. As can be seen, the operational amplifier 406A is electrically connected with a first switch S1, a second switch S2, a third switch S3, a fourth switch S4, a fifth switch S5 and a sixth switch S6. By disposing the plurality of six switches S1□S6, the operational amplifier 406A can be alternatively connected with the power supply voltage (VDDA), two-thirds of the power supply voltage (2*VDDA/3) or one-third of the power supply voltage (1*VDDA/3) as the first operation voltage V1 through the first switch S1, the second switch S2 or the third switch S3. In addition, the operational amplifier 406A may also be alternatively connected with two-thirds of the power supply voltage (2*VDDA/3), one-third of the power supply voltage (1*VDDA/3) or with the ground voltage (GNDA) as the second operation voltage V2 through the fourth switch S4, the fifth switch S5 or the sixth switch S6. Since the operational amplifier 406A is connected with the digital to analog converter 404A, and the input voltage of the operational amplifier 406A is an output voltage from the digital to analog converter 404A, it is believed that the first operation voltage V1 and the second operation voltage V2 of the operational amplifier 406A are given as analog voltage values. As such, according to the second embodiment of the present invention, the power supply voltage is illustrated as a power supply analog voltage “VDDA” in the figures, two-thirds of the power supply voltage is illustrated as a two-thirds of power supply analog voltage “2*VDDA/3” in the figures, one-third of the power supply voltage is illustrated as a one-third of power supply analog voltage “1*VDDA/3” in the figures and the ground voltage is illustrated as a ground analog voltage “GNDA” in the figures.

In the second embodiment of the present invention:
1. According to one state diagram of the disclosed driving circuit 40A as shown in FIG. 10, when the input voltage of the operational amplifier 406A is in a range between a power supply voltage (VDDA) and two-thirds of the power supply voltage (2*VDDA/3), then the first switch S1 and the fourth switch S4 are closed (while the second switch S2, the third switch S3, the fifth switch S5 and the sixth switch S6 are open), such that the first operation voltage V1 is determined and given as the power supply voltage (VDDA) and the second operation voltage V2 is determined and given as two-thirds of the power supply voltage (2*VDDA/3), respectively.
2. According to another state diagram of the disclosed driving circuit 40A as shown in FIG. 11, when the input voltage of the operational amplifier 406A is in a range between two-thirds of the power supply voltage (2*VDDA/3) and one-third of the power supply voltage (1*VDDA/3), under such circumstances, it is obvious that the second switch S2 and the fifth switch S5 are closed instead (while the first switch S1, the third switch S3, the fourth switch S4 and the sixth switch S6 are open), such that the first operation voltage V1 is determined and given as two-thirds of the power supply voltage (2*VDDA/3) and the second operation voltage V2 is determined and given as one-third of the power supply voltage (1*VDDA/3), respectively.
3. According to one another state diagram of the disclosed driving circuit 40A as shown in FIG. 12, when the input voltage of the operational amplifier 406A is in a range between one-third of the power supply voltage (1*VDDA/3) and a ground voltage (GNDA), under such circumstances, then the third switch S3 and the sixth switch S6 are closed (while the first switch S1, the second switch S2, the fourth switch S4 and the fifth switch S5 are open), such that such that the first operation voltage V1 is determined and given as one-third of the power supply voltage (1*VDDA/3) and the second operation voltage V2 is determined and given as the ground voltage (GNDA), respectively.

In view of the second embodiment of the present invention, it can be derived that by employing the adjustable first and second operation voltages V1 and V2 to the operational amplifier of a driving circuit, the present invention achieves in controlling the operational amplifier to work in another adaptive voltage range between the adjustable first operation voltage V1 and the adjustable second operation voltage V2, for example, between (VDDA□2*VDDA/3), (2*VDDA/3□1*VDDA/3) or (1*VDDA/3□GNDA). It is believed that by employing the second embodiment of the present invention, a driving circuit power consumption reduction objective of the present invention can be effectively accomplished as well.

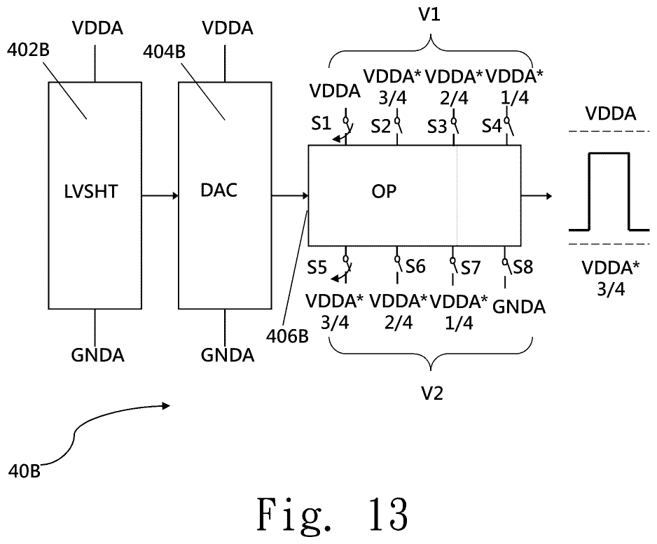

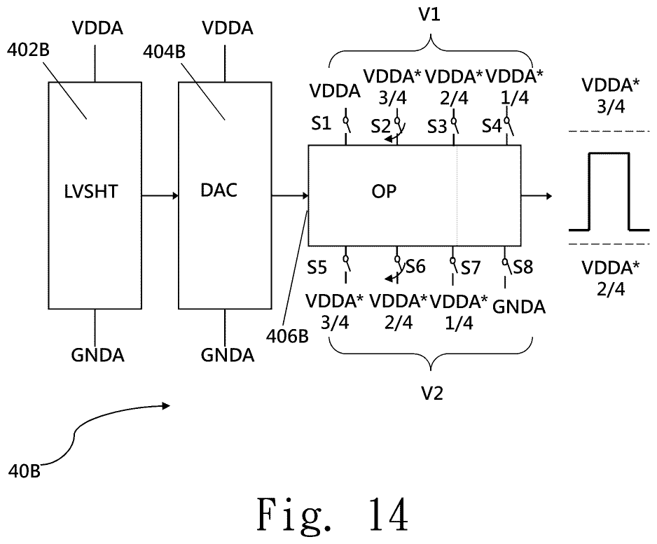

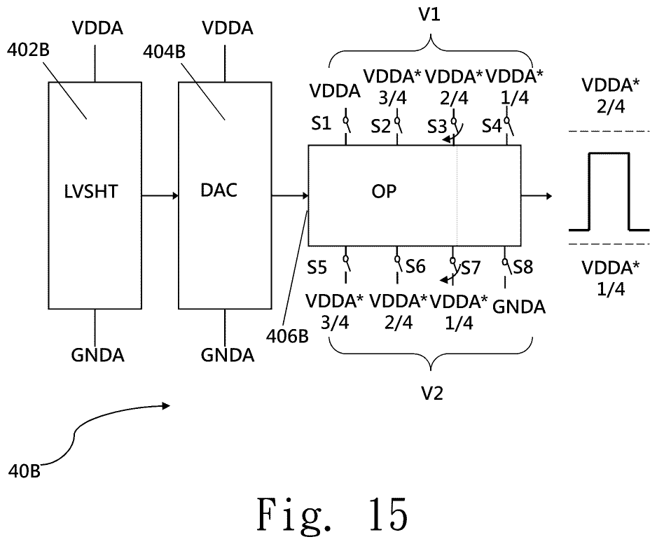

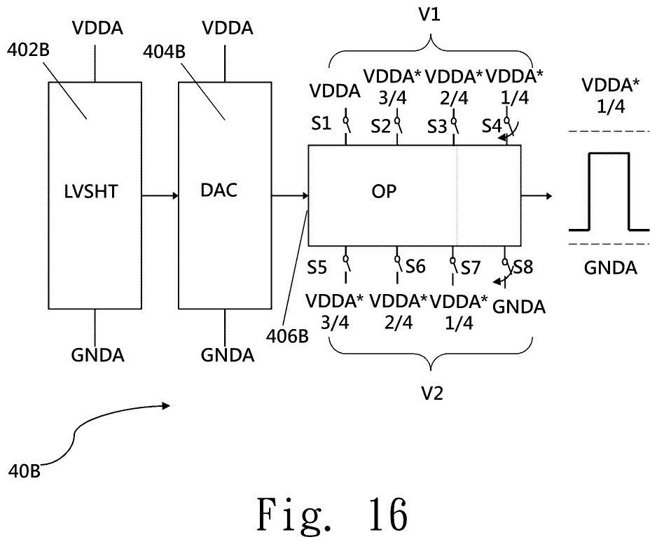

In addition, please proceed to refer to FIG. 13, FIG. 14, FIG. 15 and FIG. 16. According to these figures, the Applicants of the present invention further provide a third embodiment for implementing another proposed driving circuit applicable to drive a display panel for power consumption reduction. As illustrated in FIG. 13, FIG. 14, FIG. 15 and FIG. 16, each of the figures respectively shows one another various state diagram of the disclosed driving circuit 40B operating in one another various adaptive voltage range in accordance with the third embodiment of the present invention.

As can be seen from the schematic drawings in FIG. 13, FIG. 14, FIG. 15 and FIG. 16, the operational amplifier 406B is further electrically connected with a first switch S1, a second switch S2, a third switch S3, a fourth switch S4, a fifth switch S5, a sixth switch S6, a seventh switch S7 and an eighth switch S8. By disposing the plurality of eight switches S1□S8, the operational amplifier 406B can be alternatively connected with the power supply voltage (VDDA), three quarters of the power supply voltage (3*VDDA/4), half of the power supply voltage (2*VDDA/4) or one quarter of the power supply voltage (1*VDDA/4) as the first operation voltage V1 through the first switch S1, the second switch S2, the third switch S3 or the fourth switch S4.

And furthermore, the operational amplifier 406B may also be alternatively connected with three quarters of the power supply voltage (3*VDDA/4), half of the power supply voltage (2*VDDA/4), one quarter of the power supply voltage (1*VDDA/4) or with the ground voltage (GNDA) as the second operation voltage V2 through the fifth switch S5, the sixth switch S6, the seventh switch S7 or the eighth switch S8. Since the operational amplifier 406B is connected with the digital to analog converter 404B, and the input voltage of the operational amplifier 406B is an output voltage from the digital to analog converter 404B, it is believed that the first operation voltage V1 and the second operation voltage V2 of the operational amplifier 406B are given as analog voltage values. As such, according to the third embodiment of the present invention, the power supply voltage is illustrated as a power supply analog voltage “VDDA” in the figures, three quarters of the power supply voltage is illustrated as a three quarters of power supply analog voltage “3*VDDA/4” in the figures, half of the power supply voltage is illustrated as a half of power supply analog voltage “2*VDDA/4” in the figures, one quarter of the power supply voltage is illustrated as a one quarter of power supply analog voltage “1*VDDA/4” in the figures, and the ground voltage is illustrated as a ground analog voltage “GNDA” in the figures.

According to the third embodiment of the present invention as illustrated in FIG. 13□FIG. 16:
1. According to one state diagram of the disclosed driving circuit 40B as shown in FIG. 13, when the input voltage of the operational amplifier 406B is in a range between a power supply voltage (VDDA) and three quarters of the power supply voltage (3*VDDA/4), then the first switch S1 and the fifth switch S5 are closed (while the second switch S2, the third switch S3, the fourth switch S4, the sixth switch S6, the seventh switch S7 and the eighth switch S8 are open), such that the first operation voltage V1 is determined and given as the power supply voltage (VDDA) and the second operation voltage V2 is determined and given as three quarters of the power supply voltage (3*VDDA/4), respectively.
2. According to another state diagram of the disclosed driving circuit 40B as shown in FIG. 14, when the input voltage of the operational amplifier 406B is in a range between three quarters of the power supply voltage (3*VDDA/4) and half of the power supply voltage (2*VDDA/4), under such circumstances, it is obvious that the second switch S2 and the sixth switch S6 are closed instead (while the first switch S1, the third switch S3, the fourth switch S4, the fifth switch S5, the seventh switch S7 and the eighth switch S8 are open), such that the first operation voltage V1 is determined and given as three quarters of the power supply voltage (3*VDDA/4) and the second operation voltage V2 is determined and given as half of the power supply voltage (2*VDDA/4), respectively.
3. According to one another state diagram of the disclosed driving circuit 40B as shown in FIG. 15, when the input voltage of the operational amplifier 406B is in a range between half of the power supply voltage (2*VDDA/4) and one quarter of the power supply voltage (1*VDDA/4), under such circumstances, then the third switch S3 and the seventh switch S7 are closed (while the first switch S1, the second switch S2, the fourth switch S4, the fifth switch S5, the sixth switch S6 and the eighth switch S8 are open), such that such that the first operation voltage V1 is determined and given as half of the power supply voltage (2*VDDA/4) and the second operation voltage V2 is determined and given as one quarter of the power supply voltage (1*VDDA/4), respectively.
4. And according to one another state diagram of the disclosed driving circuit 40B as shown in FIG. 16, when the input voltage of the operational amplifier 406B is in a range between one quarter of the power supply voltage (1*VDDA/4) and the ground voltage (GNDA), under
such circumstances, then the fourth switch S4 and the eighth switch S8 are closed (while the first switch S1, the second switch S2, the third switch S3, the fifth switch S5, the sixth switch S6 and the seventh switch S7 are open), such that such that the first operation voltage V1 is determined and given as one quarter of the power supply voltage (1*VDDA/4) and the second operation voltage V2 is determined and given as the ground voltage (GNDA), respectively.

As a result, in view of the third embodiment of the present invention, it can be derived that by employing the adjustable first and second operation voltages V1 and V2 to the operational amplifier of a driving circuit, the present invention achieves in controlling the operational amplifier to work in one another adaptive voltage range between the adjustable first operation voltage V1 and the adjustable second operation voltage V2, for example, between (VDDA□3*VDDA/4), (3*VDDA/4□2*VDDA/4), (2*VDDA/4□1*VDDA/4) or (1*VDDA/4□GNDA). As a result, it is once again verified that by employing a third embodiment of the present invention, a driving circuit with power consumption reduction efficiency of the present invention can be effectively accomplished as well.

And further regarding another applicable aspect of the present invention, it is known that generally, in one display panel, there will possibly be a driving circuit composed of a plurality of operational amplifiers disposed in the configuration. As a result, assume that when a plurality of operational amplifiers are further disposed in one driving circuit as disclosed in the present invention, under such a circumstance, in order to achieve the objective for the plurality of operational amplifiers to save layout consumption, it is operable to design the adaptive voltage range between the first operation voltage and the second operation voltage of each operational amplifier to be identical such that the plurality of operational amplifiers are able to share common circuit layout (for instance, a well region) for layout area reduction.

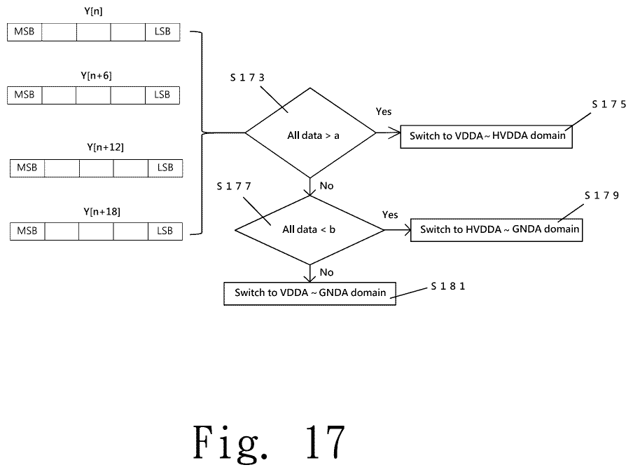

For example, please refer to FIG. 17, which schematically shows a flow chart illustrating a process method for determining the adaptive voltage range between the first operation voltage and the second operation voltage of the operational amplifier in the driving circuit when there are a plurality of operational amplifiers disposed in the driving circuit. At the same time, FIG. 18 shows the determination criteria according to FIG. 17. In both of the figures, MSB stands for the Most Significant Bit, and LSB stands for the Least Significant Bit.

As the Applicants have disclosed in the earlier paragraphs, the adaptive voltage range of each operational amplifier in Y[n], Y[n+6], Y[n+12] and Y[n+18] should be identical in order to share common circuit layout (for instance, a well region) for layout area reduction. At this time, as indicated in the step of S173, the present invention performs to examine, if all data is greater than the limitation “a” (All data>a). If yes, then step S175 is performed, such that the adaptive voltage range of the operational amplifier should be switched to (VDDA□HVDDA) domain. Otherwise, step S177 is performed, so as to further examine if all data is less than the limitation “b” (All data<b). If yes, then step S179 is performed, such that the adaptive voltage range of the operational amplifier will be switched to (HVDDA□GNDA) domain. On the other hand, if all data is not greater than the limitation “a”, and not less than the limitation “b” as well, then as indicated in the step of S181: the adaptive voltage range of the operational amplifier will be switched to a (VDDA□GNDA) domain. FIG. 18 shows the switchable voltage domain of the operational amplifier in relation to the limitations “a” and “b” in the flow chart of FIG. 17.

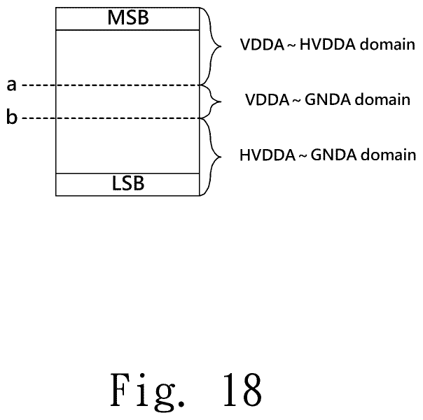

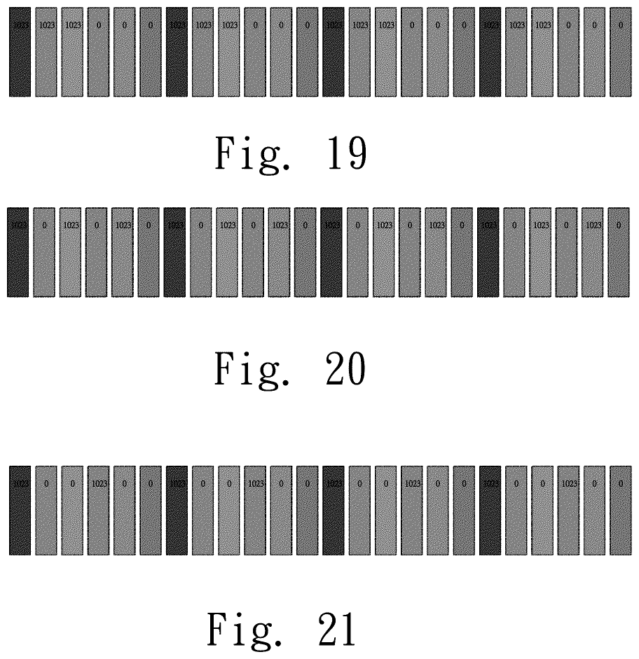

As a result, by employing the technical contents of the present invention when common circuit area can be shared in view of FIG. 17□FIG. 18, the display patterns, including a pixel checker display pattern (referring to FIG. 19), a sub-pixel checker display pattern (referring to FIG. 20) and an R/G/B display pattern (referring to FIG. 21) can be obtained. And in addition, due to the charge reuse performance as discussed in the previous FIG. 9, the adaptive voltage range of the operational amplifier can be switched either to a (VDDA□HVDDA) domain, or to a (HVDDA□GNDA) domain, it is verified that by employing the present invention, at least 50% of the power reduction efficiency can be achieved.

As a result, to sum above, it is apparent that the disclosed driving circuit for power consumption reduction and an operation method thereof the driving circuit are illustrated as above when being applied to drive a display panel. And yet, the present invention is nevertheless, not limited thereto. Other alternative and feasible circuit configuration which may be compatible is preferably practicable and thus the claim scope of the present invention covers the same. In general, those skilled in the art and having general knowledge are able to make appropriate modifications or variations with respective to the technical contents disclosed in the present invention without departing from the spirits of the present invention. And the present invention is not restricted by the certain limited configurations and/or circuit diagrams disclosed in the embodiments of the present invention. As such, it is believed that the modifications or variations should still fall into the scope of the present invention, and the present invention covers the modifications and its equality.

On account of all, based on the first, second, third, or any of the at least one embodiment as provided above, it is believed that the proposed driving circuit, which is applicable to drive the display panel for power consumption reduction and the proposed operation method for the driving circuit of the present invention have been significantly characterized. And an optimal result of power consumption reduction can be accomplished by adopting the present invention. And as a result, when compared to the related arts, it is obvious that the present invention apparently shows much more effective performances than before. In addition, it is believed that the present invention is instinct, effective and highly competitive for driving IC technology and industries in the market nowadays, whereby having extraordinary availability and competitiveness for future industrial developments and being in condition for early allowance.

It will be apparent to those skilled in the art that various modifications and variations can be made to the present invention without departing from the scope or the spirit of the invention. In view of the foregoing, it is intended that the present invention cover modifications and variations of this invention provided they fall within the scope of the invention and its equivalent.

What is claimed is:

1. An operation method for reducing power consumption of a driving circuit, wherein the
driving circuit comprises an operational amplifier and the driving circuit is applicable to drive a display panel, the operation method comprising:
determining an input voltage of the operational amplifier;
providing a first operation voltage and a second operation voltage according to the input voltage of the operational amplifier; and
electrically connecting the operational amplifier with the first operation voltage and the second operation voltage, wherein the first operation voltage and the second operation voltage are decided associated with the input voltage of the operational amplifier, such that the operational amplifier works in an adaptive voltage range between the first operation voltage and the second operation voltage.

2. The operation method for reducing power consumption of the driving circuit according to claim 1, wherein when the input voltage of the operational amplifier is in a range between a power supply voltage (VDDA) and half of the power supply voltage (HVDDA), the first operation voltage and the second operation voltage are determined and given as the power supply voltage (VDDA) and half of the power supply voltage (HVDDA), respectively.

3. The operation method for reducing power consumption of the driving circuit according to claim 2, wherein when the input voltage of the operational amplifier is in a range between half of the power supply voltage (HVDDA) and a ground voltage (GNDA), the first operation voltage and the second operation voltage are determined and given as half of the power supply voltage (HVDDA) and the ground voltage (GNDA), respectively.

4. The operation method for reducing power consumption of the driving circuit according to claim 3, wherein when the input voltage of the operational amplifier is in a range between a third operation voltage and a fourth operation voltage, and the third operation voltage is slightly greater than half of the power supply voltage (HVDDA), and the fourth operation voltage is slightly less than half of the power supply voltage (HVDDA), the first operation voltage and the second operation voltage are determined and given as the power supply voltage (VDDA) and the ground voltage (GNDA), respectively.

5. The operation method for reducing power consumption of the driving circuit according to claim 1, wherein the operational amplifier is further connected with a digital to analog converter, and the input voltage of the operational amplifier is an output voltage of the digital to analog converter.

6. The operation method for reducing power consumption of the driving circuit according to claim 5, wherein the first operation voltage and the second operation voltage of the operational amplifier are given as analog voltage values.

7. The operation method for reducing power consumption of the driving circuit according to claim 4, wherein the operational amplifier is further connected with a first switch, a second switch, a third switch, and a fourth switch, such that the operational amplifier is alternatively connected with the power supply voltage (VDDA) or with half of the power supply voltage (HVDDA) as the first operation voltage through the first switch or the second switch, and the operational amplifier is alternatively connected with half of the power supply voltage (HVDDA) or with the ground voltage (GNDA) as the second operation voltage through the third switch or the fourth switch.

8. The operation method for reducing power consumption of the driving circuit according to claim 1, wherein when the input voltage of the operational amplifier is in a range between a power supply voltage (VDDA) and two-thirds of the power supply voltage (2*VDDA/3), the first operation voltage and the second operation voltage are determined and given as the power supply voltage (VDDA) and two-thirds of the power supply voltage (2*VDDA/3), respectively.

9. The operation method for reducing power consumption of the driving circuit according to claim 8, wherein when the input voltage of the operational amplifier is in a range between two-thirds of the power supply voltage (2*VDDA/3) and one-third of the power supply voltage (1*VDDA/3), the first operation voltage and the second operation voltage are determined and given as two-thirds of the power supply voltage (2*VDDA/3) and one-third of the power supply voltage (1*VDDA/3), respectively.

10. The operation method for reducing power consumption of the driving circuit according to claim 9, wherein when the input voltage of the operational amplifier is in a range between one-third of the power supply voltage (1*VDDA/3) and a ground voltage (GNDA), the first operation voltage and the second operation voltage are determined and given as one-third of the power supply voltage (1*VDDA/3) and the ground voltage (GNDA), respectively.

11. The operation method for reducing power consumption of the driving circuit according to claim 10, wherein the operational amplifier is further connected with a first switch, a second switch, a third switch, a fourth switch, a fifth switch and a sixth switch, such that the operational amplifier is alternatively connected with the power supply voltage (VDDA), two-thirds of the power supply voltage (2*VDDA/3) or one-third of the power supply voltage (1*VDDA/3) as the first operation voltage through the first switch, the second switch or the third switch, and the operational amplifier is alternatively connected with two-thirds of the power supply voltage (2*VDDA/3), one-third of the power supply voltage (1*VDDA/3) or with the ground voltage (GNDA) as the second operation voltage through the fourth switch, the fifth switch or the sixth switch.

12. The operation method for reducing power consumption of the driving circuit according to claim 1, wherein when the input voltage of the operational amplifier is in a range between a power supply voltage (VDDA) and three quarters of the power supply voltage (3*VDDA/4), the first operation voltage and the second operation voltage are determined and given as the power supply voltage (VDDA) and three quarters of the power supply voltage (3*VDDA/4), respectively.

13. The operation method for reducing power consumption of the driving circuit according to claim 12, wherein when the input voltage of the operational amplifier is in a range between three quarters of the power supply voltage (3*VDDA/4) and half of the power supply voltage (2*VDDA/4), the first operation voltage and the second operation voltage are determined and given as three quarters of the power supply voltage (3*VDDA/4) and half of the power supply voltage (2*VDDA/4), respectively.

14. The operation method for reducing power consumption of the driving circuit according to claim 13, wherein when the input voltage of the operational amplifier is in a range between half of the power supply voltage (2*VDDA/4) and one quarter of the power supply voltage (1*VDDA/4), the first operation voltage and the second operation voltage are determined and given as half of the power supply voltage (2*VDDA/4) and one quarter of the power supply voltage (1*VDDA/4), respectively.

15. The operation method for reducing power consumption of the driving circuit according to claim 14, wherein when the input voltage of the operational amplifier is in a range between one quarter of the power supply voltage (1*VDDA/4) and a ground voltage (GNDA), the first operation voltage and the second operation voltage are determined and given as one quarter of the power supply voltage (1*VDDA/4) and the ground voltage (GNDA), respectively.

16. The operation method for reducing power consumption of the driving circuit according to claim 15, wherein the operational amplifier is further connected with a first switch, a second switch, a third switch, a fourth switch, a fifth switch, a sixth switch, a seventh switch and an eighth switch, such that the operational amplifier is alternatively connected with the power supply voltage (VDDA), three quarters of the power supply voltage (3*VDDA/4), half of the power supply voltage (2*VDDA/4) or one quarter of the power supply voltage (1*VDDA/4) as the first operation voltage through the first switch, the second switch, the third switch or the fourth switch, and the operational amplifier is alternatively connected with three quarters of the power supply voltage (3*VDDA/4), half of the power supply voltage (2*VDDA/4), one quarter of the power supply voltage (1*VDDA/4) or with the ground voltage (GNDA) as the second operation voltage through the fifth switch, the sixth switch, the seventh switch or the eighth switch.

17. The operation method for reducing power consumption of the driving circuit according to claim 1, wherein when a plurality of the operational amplifiers are further disposed in the driving circuit, the adaptive voltage range between the first operation voltage and the second operation voltage of each of the plurality of the operational amplifiers is identical for the plurality of the operational amplifiers sharing common circuit layout for layout area reduction.

18. A driving circuit for power consumption reduction, which is applicable to drive a display
panel, comprising:
a level shifter circuit,
a digital to analog converter, being electrically connected with the level shifter circuit; and
an operational amplifier, being electrically connected with the digital to analog converter, wherein an output voltage of the digital to analog converter is an input voltage of the operational amplifier, the operational amplifier is electrically supplied with a first operation voltage and a second operation voltage, and the first operation voltage and the second operation voltage are decided associated with the input voltage of the operational amplifier, such that the operational amplifier works in an adaptive voltage range between the first operation voltage and the second operation voltage.

19. The driving circuit for power consumption reduction, which is applicable to drive the display panel according to claim 18, wherein the first operation voltage and the second operation voltage of the operational amplifier are given as analog voltage values.

20. The driving circuit for power consumption reduction, which is applicable to drive the display panel according to claim 18, wherein when the input voltage of the operational amplifier is in a range between a power supply voltage (VDDA) and half of the power supply voltage (HVDDA), the first operation voltage and the second operation voltage are determined and given as the power supply voltage (VDDA) and half of the power supply voltage (HVDDA), respectively.

21. The driving circuit for power consumption reduction, which is applicable to drive the display panel according to claim 20, wherein when the input voltage of the operational amplifier is in a range between half of the power supply voltage (HVDDA) and a ground voltage (GNDA), the first operation voltage and the second operation voltage are determined and given as half of the power supply voltage (HVDDA) and the ground voltage (GNDA), respectively.

22. The driving circuit for power consumption reduction, which is applicable to drive the display panel according to claim 21, wherein when the input voltage of the operational amplifier is in a range between a third operation voltage and a fourth operation voltage, and the third operation voltage is slightly greater than half of the power supply voltage (HVDDA), and the fourth operation voltage is slightly less than half of the power supply voltage (HVDDA), the first operation voltage and the second operation voltage are determined and given as the power supply voltage (VDDA) and the ground voltage (GNDA), respectively.

23. The driving circuit for power consumption reduction, which is applicable to drive the display panel according to claim 22, wherein the operational amplifier is further connected with a first switch, a second switch, a third switch, and a fourth switch, such that the operational amplifier is alternatively connected with the power supply voltage (VDDA) or with half of the power supply voltage (HVDDA) as the first operation voltage through the first switch or the second switch, and the operational amplifier is alternatively connected with half of the power supply voltage (HVDDA) or with the ground voltage (GNDA) as the second operation voltage through the third switch or the fourth switch.

24. The driving circuit for power consumption reduction, which is applicable to drive the display panel according to claim 18, wherein when the input voltage of the operational amplifier is in a range between a power supply voltage (VDDA) and two-thirds of the power supply voltage (2*VDDA/3), the first operation voltage and the second operation voltage are determined and given as the power supply voltage (VDDA) and two-thirds of the power supply voltage (2*VDDA/3), respectively.

25. The driving circuit for power consumption reduction, which is applicable to drive the display panel according to claim 24, wherein when the input voltage of the operational amplifier is in a range between two-thirds of the power supply voltage (2*VDDA/3) and one-third of the power supply voltage (1*VDDA/3), the first operation voltage and the second operation voltage are determined and given as two-thirds of the power supply voltage (2*VDDA/3) and one-third of the power supply voltage (1*VDDA/3), respectively.

26. The driving circuit for power consumption reduction, which is applicable to drive the display panel according to claim 25, wherein when the input voltage of the operational amplifier is in a range between one-third of the power supply voltage (1*VDDA/3) and a ground voltage (GNDA), the first operation voltage and the second operation voltage are determined and given as one-third of the power supply voltage (1*VDDA/3) and the ground voltage (GNDA), respectively.

27. The driving circuit for power consumption reduction, which is applicable to drive the display panel according to claim 26, wherein the operational amplifier is further connected with a first switch, a second switch, a third switch, a fourth switch, a fifth switch and a sixth switch, such that the operational amplifier is alternatively connected with the power supply voltage (VDDA), two-thirds of the power supply voltage (2*VDDA/3) or one-third of the power supply voltage (1*VDDA/3) as the first operation voltage through the first switch, the second switch or the third switch, and the operational amplifier is alternatively connected with two-thirds of the power supply voltage (2*VDDA/3), one-third of the power supply voltage (1*VDDA/3) or with the ground voltage (GNDA) as the second operation voltage through the fourth switch, the fifth switch or the sixth switch.

28. The driving circuit for power consumption reduction, which is applicable to drive the display panel according to claim 18, wherein when the input voltage of the operational amplifier is in a range between a power supply voltage (VDDA) and three quarters of the power supply voltage (3*VDDA/4), the first operation voltage and the second operation voltage are determined and given as the power supply voltage (VDDA) and three quarters of the power supply voltage (3*VDDA/4), respectively.

29. The driving circuit for power consumption reduction, which is applicable to drive the display panel according to claim 28, wherein when the input voltage of the operational amplifier is in a range between three quarters of the power supply voltage (3*VDDA/4) and half of the power supply voltage (2*VDDA/4), the first operation voltage and the second operation voltage are determined and given as three quarters of the power supply voltage (3*VDDA/4) and half of the power supply voltage (2*VDDA/4), respectively.

30. The driving circuit for power consumption reduction, which is applicable to drive the display panel according to claim 29, wherein when the input voltage of the operational amplifier is in a range between half of the power supply voltage (2*VDDA/4) and one quarter of the power supply voltage (1*VDDA/4), the first operation voltage and the second operation voltage are determined and given as half of the power supply voltage (2*VDDA/4) and one quarter of the power supply voltage (1*VDDA/4), respectively.

31. The driving circuit for power consumption reduction, which is applicable to drive the display panel according to claim 30, wherein when the input voltage of the operational amplifier is in a range between one quarter of the power supply voltage (1*VDDA/4) and a ground voltage (GNDA), the first operation voltage and the second operation voltage are determined and given as one quarter of the power supply voltage (1*VDDA/4) and the ground voltage (GNDA), respectively.

32. The driving circuit for power consumption reduction, which is applicable to drive the display panel according to claim 31, wherein the operational amplifier is further connected with a first switch, a second switch, a third switch, a fourth switch, a fifth switch, a sixth switch, a seventh switch and an eighth switch, such that the operational amplifier is alternatively connected with the power supply voltage (VDDA), three quarters of the power supply voltage (3*VDDA/4), half of the power supply voltage (2*VDDA/4) or one quarter of the power supply voltage (1*VDDA/4) as the first operation voltage through the first switch, the second switch, the third switch or the fourth switch, and the operational amplifier is alternatively connected with three quarters of the power supply voltage (3*VDDA/4), half of the power supply voltage (2*VDDA/4), one quarter of the power supply voltage (1*VDDA/4) or with the ground voltage (GNDA) as the second operation voltage through the fifth switch, the sixth switch, the seventh switch or the eighth switch.

33. The driving circuit for power consumption reduction, which is applicable to drive the display panel according to claim 18, wherein when a plurality of the operational amplifiers are further disposed in the driving circuit, the adaptive voltage range between the first operation voltage and the second operation voltage of each of the plurality of the operational amplifiers is identical for the plurality of the operational amplifiers sharing common circuit layout for layout area reduction.
